(19) United States
(12) Patent Application Publication
(10) Pub. No.: US 2025/0344420 A1
(43) Pub. Date: Nov. 6, 2025

(54) NANOSTRUCTURE FIELD-EFFECT TRANSISTOR DEVICE AND METHODS OF FORMING

(71) Applicant: Taiwan Semiconductor Manufacturing Co., Ltd., Hsinchu (TW)

(72) Inventors: Ya-Chu Lee, Tainan City (TW); Sih-Jie Liu, Hsinchu (TW); Liang-Yin Chen, Hsinchu (TW); Chien-Hao Chen, Chuangwei Township (TW)

(21) Appl. No.: 18/761,640

(22) Filed: Jul. 2, 2024

Related U.S. Application Data
(60) Provisional application No. 63/640,911, filed on May 1, 2024.

(51) Int. Cl. H01L 29/66; H01L 21/225; H01L 21/265; H01L 29/06; H01L 29/08; H01L 29/423; H01L 29/775; H01L 29/786

(52) U.S. Cl. CPC H10D 30/014; H01L 21/2253; H01L 21/26513; H10D 30/43; H10D 30/6735; H10D 30/6757; H10D 62/121; H10D 62/151; H10D 64/017; H10D 64/018

(57) ABSTRACT

A method of forming a semiconductor device includes: forming a fin structure that protrudes above a substrate, where the fin structure includes a fin and a layer stack overlying the fin, where the layer stack includes alternating layers of a first semiconductor material and a second semiconductor material; forming a gate structure over the fin structure; forming source/drain openings in the fin structure on opposing sides of the gate structure; replacing first end portions of the first semiconductor material exposed by the source/drain openings with inner spacers; after the replacing, performing an ion implantation process, where the ion implantation process implants a first dopant into second end portions of the second semiconductor material exposed by the source/drain openings; and after performing the ion implantation process, forming source/drain regions in the source/drain openings.

### PRIORITY CLAIM AND CROSS-REFERENCE

This application claims priority to U.S. Provisional Patent Application No. 63/640,911, filed May 1, 2024, entitled “Nano-Sheet Resistance Reduction by Ion Implantation Approach,” which application is hereby incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A-3C, 4A, 4B, 5A-5C, 6A-6D, 7A, 7B, 8A-8D, 9A, 9B, 10A, 10B, 11A, 11B, 12A, and 12B are cross-sectional views of a nanostructure field-effect transistor (NSFET) device at various stages of manufacturing, in accordance with an embodiment.

FIG. 13 illustrate a flow chart of a method of forming a semiconductor device, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

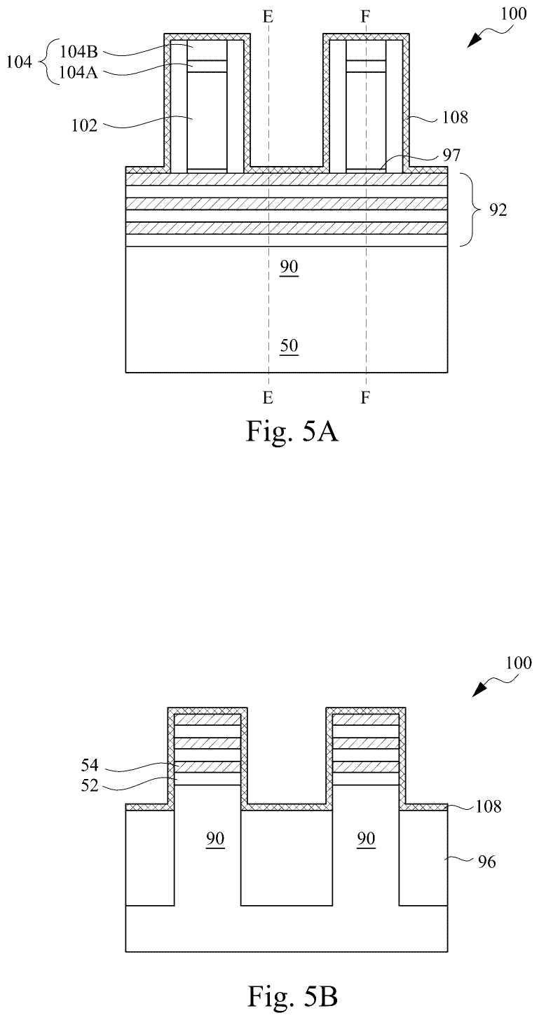

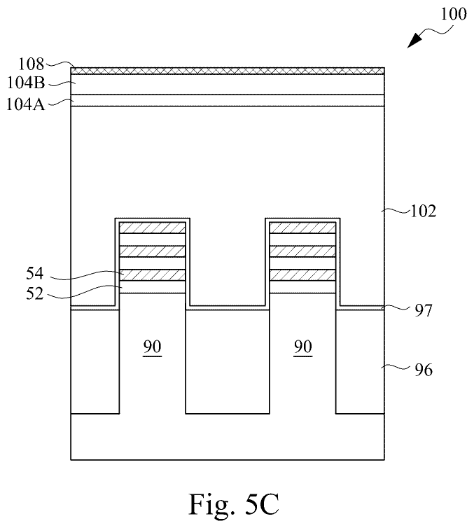

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise described, the same or similar reference numeral in different figures refer to the same or similar component formed by a same or similar formation process using a same or similar material(s). In addition, figures with the same numeral but different alphabets (e.g., FIGS. 5A-5C) illustrate different views of the NSFET device at the same stage of processing.

In accordance with some embodiments, during a process to form an NSFET device, after the source/drain openings are formed, an ion implantation process is performed to implant a dopant into end portions of layers of a semiconductor material in a layer stack, where the end portions are exposed by the source/drain openings. The layers of the semiconductor material in the layer stack will form channel regions of the NSFET device in subsequent processing. The dopant is implanted in doped regions of the semiconductor material. The doped regions have higher carrier mobility and lower electrical resistance than undoped regions of the semiconductor material. Therefore, by forming the doped regions in the layers of the semiconductor material, electrical resistance of the channel regions of the NSFET device formed is reduced, and the electrical performance of the NSFET device is improved.

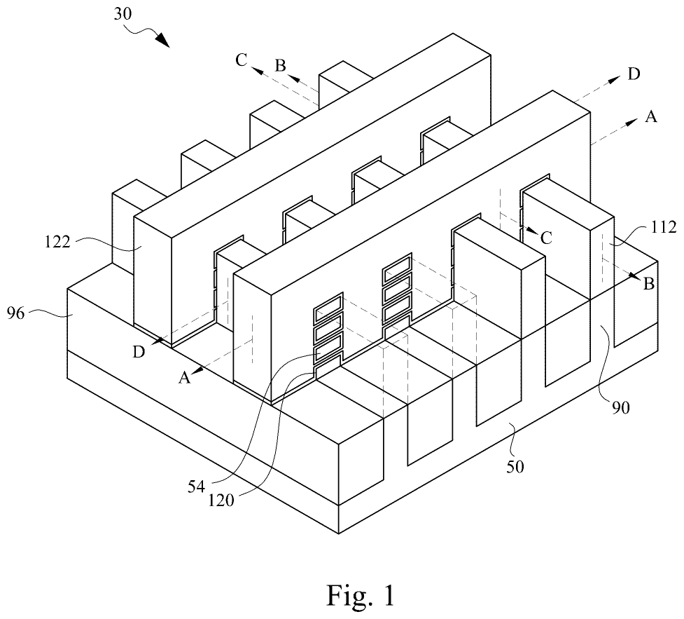

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the gate electrode 122 and in a direction, for example, perpendicular to the direction of current flow between the source/drain regions 112 of the NSFET device 30. Cross-section B-B is perpendicular to cross-section A-A and is along a longitudinal axis of the fin 90 and in a direction of, for example, a current flow between the source/drain regions 112 of the NSFET device. Cross-section C-C is parallel to cross-section B-B and between two neighboring fins 90. Cross-section D-D is parallel to cross-section A-A and extends through source/drain regions 112 of the NSFET device. Subsequent figures may refer to these reference cross-sections for clarity.

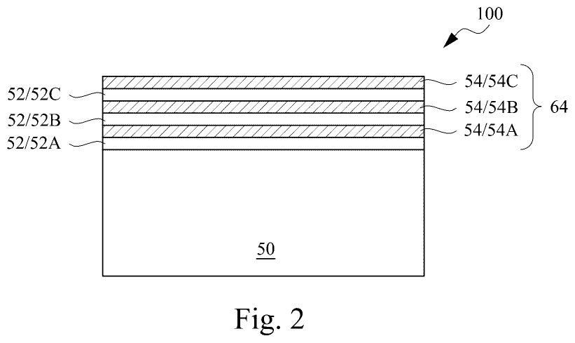

FIGS. 2, 3A-3C, 4A, 4B, 5A-5C, 6A-6D, 7A, 7B, 8A-8D, 9A, 9B, 10A, 10B, 11A, 11B, 12A, and 12B are cross-sectional views of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. In some embodiments, the second semiconductor material 54 (e.g., silicon) may be used to form both n-type or p-type FETs, and the first semiconductor material 52 is used as a sacrificial material that is removed later. The multi-layer stack 64 (which may also be referred to as an epitaxial material stack) will be patterned to form channel regions of an NSFET in subsequent processing. In particular, the multi-layer stack 64 will be patterned and etched to form horizontal nanostructures (e.g., nanosheets or nanowires), with the channel regions of the resulting NSFET including multiple horizontal nanostructures.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

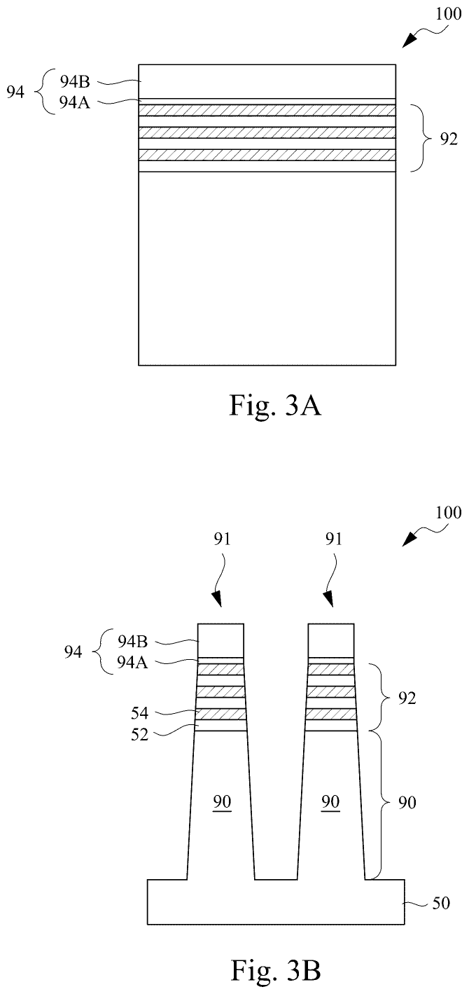

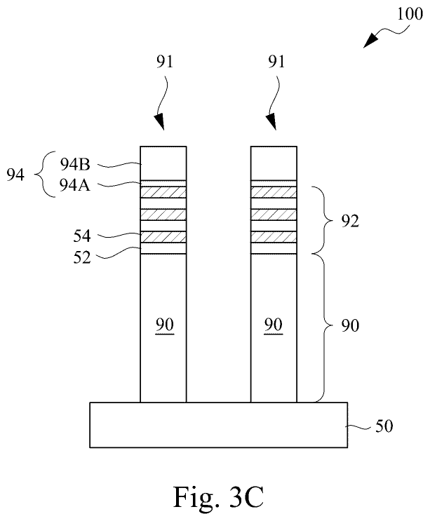

FIGS. 3A-3C, 4A, 4B, 5A-5C, 6A-6D, 7A, 7B, 8A-8D, 9A, 9B, 10A, 10B, 11A, 11B, 12A, and 12B are cross-sectional views of the NSFET device 100 at subsequent stages of manufacturing, in accordance with an embodiment. FIGS. 3A, 4A, 5A, 6A, 6D, 7A, 7B, 8A, 8D, 9A, 10A, 11A, and 12A are cross-sectional views along cross-section B-B in FIG. 1. FIGS. 3B, 3C, 4B, 5C, 6C, 8C, 9B, 10B, 11B, and 12B are cross-sectional views along cross-section A-A in FIG. 1. FIGS. 5B, 6B, and 8B are cross-sectional views along cross-section D-D in FIG. 1. The number of fins and the number of gate structures illustrated in the figures are merely a non-limiting example, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etch process, such as a reactive ion etch (RIE), neutral beam etch (NBE), the like, or a combination thereof. The etching is an anisotropic etching process, in some embodiments. After the etching process, the patterned multi-layer stack 64 forms the layer stack 92, and the patterned substrate 50 forms the fin 90, as illustrated in FIGS. 3A and 3B. Therefore, in the illustrated embodiment, the layer stack 92 also includes alternating layers of the first semiconductor material 52 and the second semiconductor material 54, and the fin 90 is formed of a same material (e.g., silicon) as the substrate 50.

The fins 90 and the layer stacks 92 in FIG. 3B are illustrated to have sloped sidewalls (e.g., having trapezoidal cross-sections). The sloped sidewalls illustrated in FIG. 3B may be formed due to the properties of the anisotropic etching process used to form the fins 90 and the layer stacks 92. For example, the etching capability of the anisotropic etching process may decrease along the downward vertical direction of FIG. 3B, which may result in the sloped sidewalls. The shapes of the fins 90 and the layer stacks 92 illustrated in FIG. 3B are merely non-limiting examples. The fins 90 and the layer stack 92 may have substantially perpendicular sidewalls, as illustrated in FIG. 3C. For ease of illustration, the fins 90 and the layer stack 92 may be illustrated in subsequent figures as having perpendicular sidewalls, with the understanding that the sidewalls may be sloped as illustrated in FIG. 3B.

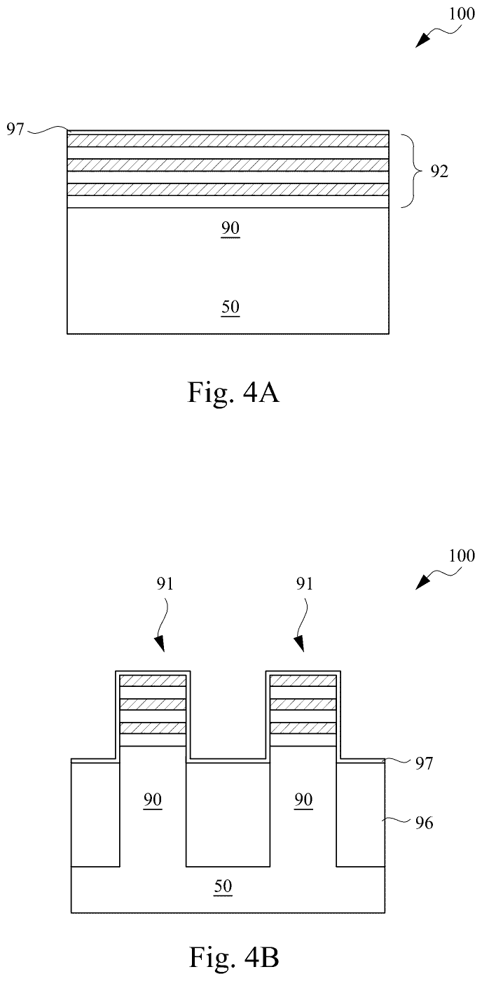

Next, in FIGS. 4A and 4B, Shallow Trench Isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. In some embodiments, a planarization process such as a chemical mechanical polish (CMP), an etch back process, combinations thereof, or the like, may be utilized. The planarization process exposes the layer stacks 92 such that top surfaces of the layer stacks 92 and the insulation material are level after the planarization process is complete. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than the material of the fin 90 and the layer stack 92). For example, a chemical oxide removal with a suitable etchant such as dilute hydrofluoric (dHF) acid may be used.

Still referring to FIGS. 4A and 4B, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques. In an embodiment, a layer of silicon is conformally formed over the layer stack 92 and over the upper surface of the STI regions 96, and a thermal oxidization process is performed to convert the deposited silicon layer into an oxide layer as the dummy dielectric layer 97.

Next, in FIGS. 5A-5C, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by a CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gate 102 and the dummy gate dielectric 97 are collectively referred to as dummy gate structure, in some embodiments.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections D-D and A-A in FIG. 1, respectively.

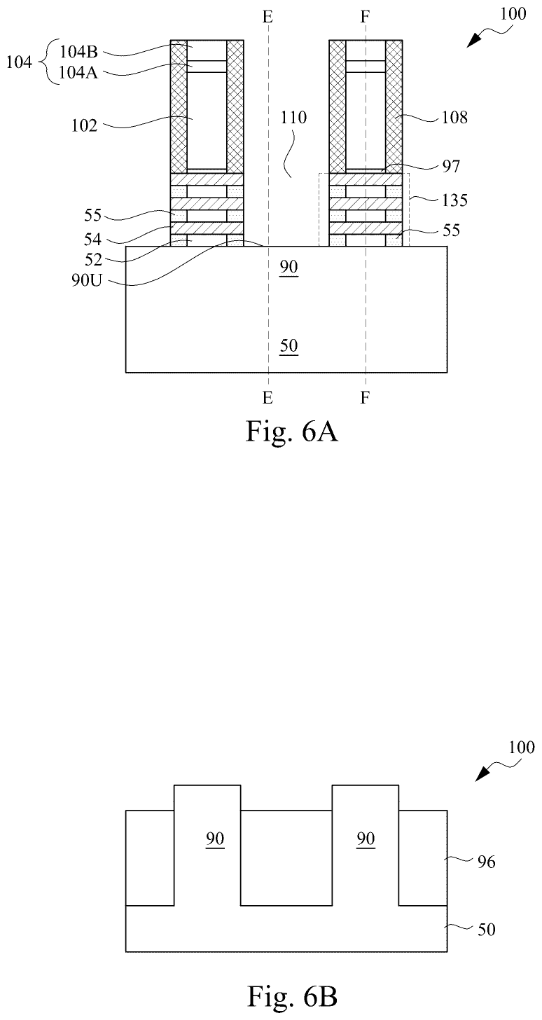

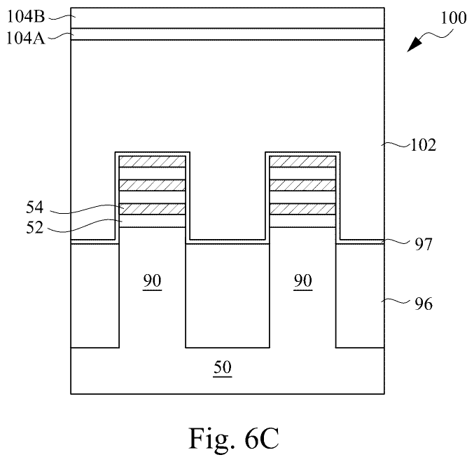

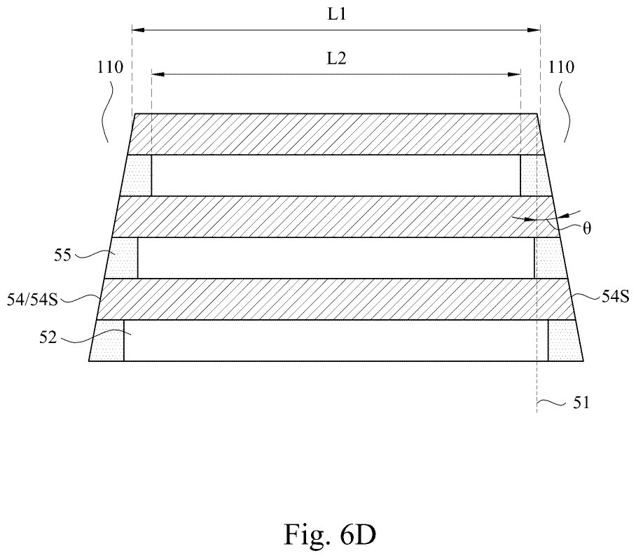

Next, in FIGS. 6A-6C, the gate spacer layers 108 are etched by an anisotropic etching process to form gate spacers 108. The anisotropic etching process may remove horizontal portions of the gate spacer layer 108 (e.g., portions over the STI regions 96 and the dummy gates 102), with remaining vertical portions of the gate spacer layer 108 (e.g., portions along sidewalls of the dummy gates 102 and the dummy gate dielectric 97) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or semiconductor fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities between about 1E15/cm³ and about 1E16/cm³. An anneal process may be used to activate the implanted impurities.

Next, openings 110 (which may also be referred to as recesses, or source/drain openings) are formed in the layer stacks 92. The openings 110 may extend through the layer stacks 92 and into the fins 90. The openings 110 may be formed by an anisotropic etching process using, e.g., the dummy gates 102 and the gate spacers 108 as an etching mask.

After the openings 110 are formed, a selective etching process is performed to recess end portions of the first semiconductor material 52 exposed by the openings 110 without substantially attacking the second semiconductor material 54. After the selective etching process, recesses (also referred to as sidewall recesses) are formed in the first semiconductor material 52 at locations where the removed end portions used to be.

Next, an inner spacer layer is formed (e.g., conformally) in the openings 110. The inner spacer layer also fills the sidewall recesses of the first semiconductor material 52 formed by the previous selective etching process. The inner spacer layer may be a suitable dielectric material, such as silicon carbonitride (SiCN), silicon oxycarbonitride (SiOCN), or the like, formed by a suitable deposition method such as PVD, CVD, atomic layer deposition (ALD), or the like. Next, an etching process, such as an anisotropic etching process, is performed to remove portions of the inner spacer layer disposed outside the sidewall recesses of the first semiconductor material 52. The remaining portions of the inner spacer layer (e.g., portions disposed inside the sidewall recesses of the first semiconductor material 52) form inner spacers 55. As illustrated in FIG. 6A, the openings 110 expose sidewalls of the second semiconductor material 54, and expose upper surfaces 90U of the fins 90 at the bottoms of the openings 110.

FIGS. 6B and 6C illustrate cross-sectional views of the NSFET device 100 in FIG. 6A along cross-sections E-E and F-F, respectively. In FIG. 6B, the portions of the gate spacer layer 108 disposed on the upper surface of the STI regions 96 between neighboring fins 90 are completely removed by the anisotropic etching process used for forming the gate spacers 108. In some embodiments, portions of the gate spacer layer 108 are left (e.g., remain) between neighboring fins 90 on the upper surface of the STI regions 96. Those portions of the gate spacer layer 108 may be left because the anisotropic etching process discussed above may not completely remove the gate spacer layer 108 disposed between neighboring fins 90, due to the small distance between the neighboring fins 90 reducing efficiency of the anisotropic etching process.

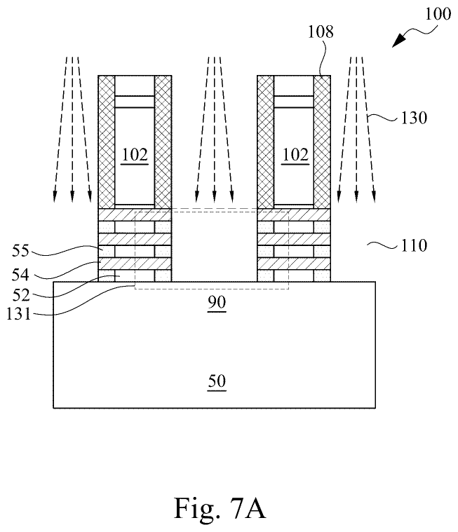

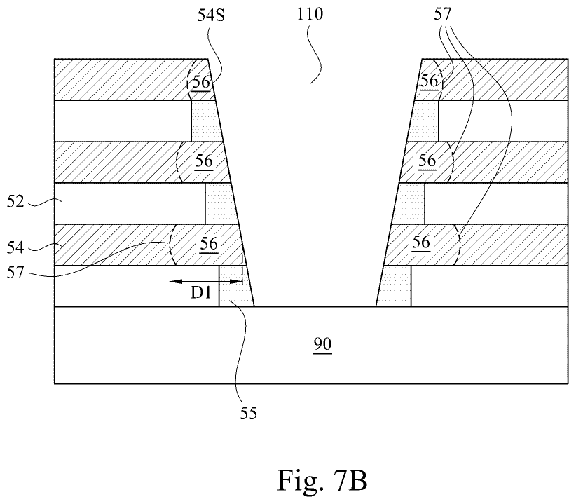

Note that for ease of illustration, the openings 110 in FIG. 6A are illustrated as having perpendicular sidewalls (e.g., perpendicular to a major upper surface of the substrate 50). The openings 110 may actually have sloped sidewalls, as illustrated in FIGS. 6D and 7B. In some embodiments, each of the openings 110 has sloped sidewalls such that a width of the opening 110, measured between opposing sidewalls of the opening 110, decreases (see, e.g., FIG. 7B) as the opening 110 extends toward the substrate 50. In other words, the opening 110 may have a trapezoidal cross-section. As a result, the structure under each dummy gate 102 in FIG. 6A, which structure includes layers of the first semiconductor material 52, layers of the second semiconductor material 54, and the inner spacers 55, may also have a trapezoidal cross-section. FIG. 6D illustrates a zoomed-in view of an area 135 in FIG. 6A.

In the example of FIG. 6D, each layer of the second semiconductor material 54 has sloped sidewalls 54S (e.g., having a trapezoidal cross-section). In addition, a length L1 of each layer of the second semiconductor material 54, measured between neighboring openings 110 at a midpoint between an upper surface and a lower surface of the layer of the second semiconductor material 54, increases along a depth direction (e.g., a vertical direction 51 in FIG. 6D) of the openings 110 toward the substrate 50. In some embodiments, an angle θ between the sloped sidewall 54S of the second semiconductor material 54 and the vertical direction 51 is between about 0.5 degree and about 30 degrees, such as between about 5 degrees and about 25 degrees, or between about 10 degrees and about 20 degrees. In the illustrated example of FIG. 6D, each of the inner spacers 55 also has a trapezoidal cross-section, with one sloped sidewall and one perpendicular sidewall. In FIG. 6D, the layers of the first semiconductor material 52 have rectangular cross-sections, and a length L2 of each layer of the first semiconductor material 52 increases along the vertical direction 51 toward the substrate 50.

Note that for ease of illustration, perpendicular sidewalls (e.g., perpendicular to the major upper surface of the substrate 50) are shown for, e.g., some sidewalls of the second semiconductor material 54, the inner spacers 55, the openings 110, and the source/drain regions 112 in FIGS. 6A, 7A, 8A, 9A, 10A, 11A, and 12A, with the understanding that sloped sidewalls such as those illustrated in FIGS. 6D, 7B, and 8D are formed in the NSFET device 100.

Next, in FIG. 7A, an ion implantation process 130 is performed to implant a first dopant into end portions of the second semiconductor material 54 exposed by the openings 110. The first dopant may be an n-type dopant or a p-type dopant, depending on the type of device formed. In the illustrated embodiment, the first dopant is of a same type (e.g., n-type or p-type) as a second dopant in subsequently formed source/drain regions 112. In other words, the first dopant is of the same type (e.g., n-type or p-type) as the NSFET formed. The first dopant may be any suitable n-type impurities (e.g., P, Sb, or As) or p-type impurities (e.g., B, Al, Ga, or In) used by the ion implantation process 130.

In some embodiments, the ion implantation process 130 is performed at a temperature between about −100° C. and about 300° C. A tilt angle of the ion implantation process 130 may be between about 0 degree and about 45 degrees. An energy of the ion implantation process 130 may be between about 0.2 kiloelectron volts (KeV) and about 20 KeV. A dosage of the ion implantation process 130 may be between about 1E16/cm² and about 1E20/cm². After the ion implantation process 130 is finished, a thermal process (e.g., an anneal process) is performed to activate the first dopant implanted into the end portions of the second semiconductor material 54, in some embodiments.

FIG. 7B illustrates a zoomed-in view of an area 131 in FIG. 7A after the ion implantation process 130 and the thermal process to activate the first dopant are finished. In FIG. 7B, doped regions 56 of the second semiconductor material 54 are illustrated, which doped regions 56 are regions of the second semiconductor material 54 comprising the first dopant. For each doped region 56, a boundary 57 (e.g., an interface) between the doped region 56 and the undoped portion of the second semiconductor material 54 is illustrated in dashed line. The boundary 57 may also be referred to as a junction 57.

In the illustrated example of FIG. 7B, due to the sloped sidewalls 54S of the second semiconductor material 54 and the ion beam divergence (and/or higher tilt angle of the ion beam), lower layers (e.g., closer to the substrate 50) of the second semiconductor material 54 receive (e.g., are implanted with) more of the first dopant. As a result, the concentration of the first dopant in the doped regions 56 increases along the depth direction of the opening 110 toward the substrate 50. In other words, the closer is the doped region 56 to the substrate 50, the higher is the concentration of the first dopant in the doped region 56. In some embodiments, the concentration of the first dopant in the lowermost doped region 56 (e.g., closest to the substrate 50) is between about twice and about five times that of the uppermost doped region 56 (e.g., furthest from the substrate 50).

The first dopant, once implanted in the end portions of the second semiconductor material 54 and activated, also diffuses further toward the center portion of the second semiconductor material 54. Each doped region 56 in FIG. 7B therefore includes the region with implanted first dopant and the region with diffused first dopant. In the example of FIG. 7B, the width D1 of the doped regions 56 (e.g., a maximum width measured between the sloped sidewall 54S of the second semiconductor material 54 and the respective boundary 57 of the doped region 56) increases along the depth direction of the opening 110 (e.g., the vertical direction in FIG. 7B) toward the substrate 50. In other words, the lower is the doped region 56, the larger is the width D1 of the doped region 56. A larger width D1 indicates a larger volume of the doped region 56, in some embodiments.

In some embodiments, after the thermal process to activate the first dopant, the first dopant (e.g., ions of boron) in the doped regions 56 replaces atoms (e.g., silicon atoms) in the lattice structure of the second semiconductor material 54 (e.g., silicon), and therefore, are disposed in substitutional positions of the lattice structure. The doped regions 56 have increased carrier mobility and lower electrical resistance. Since the second semiconductor material 54 forms the channel regions of the NSFET device 100 in subsequent processing, a larger doped region 56 (e.g., with a larger width D1 and/or a larger volume) in the second semiconductor material 54 decreases the electrical resistance of the channel regions of the NSFET device formed, thus improving the electrical performance of the NSFET device.

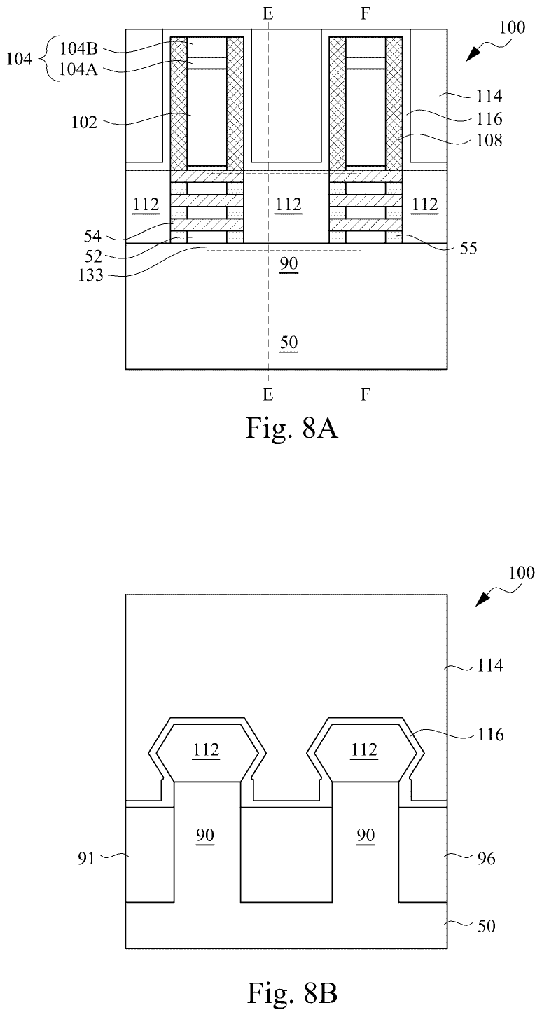

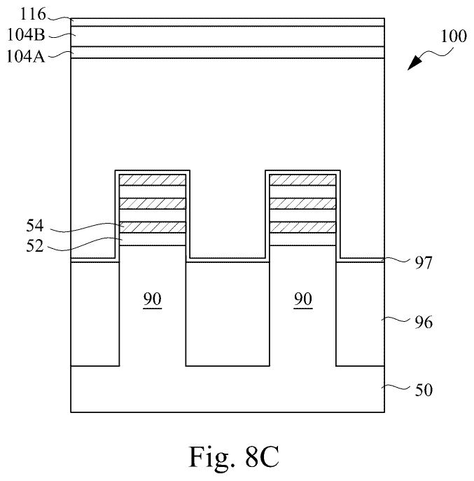

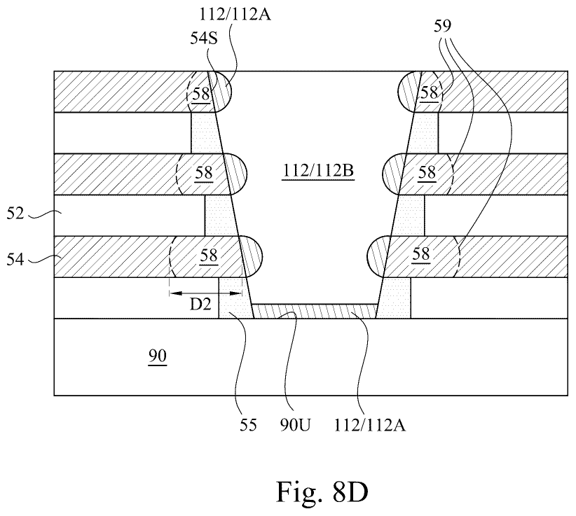

Next, in FIG. 8A-8C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed gates of the resulting NSFET device.

The epitaxial source/drain regions 112 are epitaxially grown in the openings 110. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with a second dopant (e.g., n-type impurities or p-type impurities) to form source/drain regions, similar to the process previously discussed for forming lightly-doped source/drain regions, followed by an anneal. The source/drain regions may have an impurity concentration (may also be referred to as a dopant concentration) of between about 1E19/cm³ and about 1E21/cm³. The n-type and/or p-type impurities for source/drain regions may be any of the impurities previously discussed. In some embodiments, the epitaxial source/drain regions 112 may be in situ doped during growth. As discussed above, the first dopant in the doped regions 56 and the second dopant in the source/drain regions 112 are of a same type (e.g., n-type or p-type). The first dopant may be the same as the second dopant, or may be different from the second dopant but of the same type.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIG. 8B) after the epitaxy process is completed. In other embodiments, these facets cause adjacent epitaxial source/drain regions 112 of a same NSFET to merge.

FIG. 8D shows a zoomed-in view of an area 133 in FIG. 8A. In the example of FIG. 8D, the source/drain region 112 includes a first layer of source/drain material 112A and a second layer of source/drain material 112B. In some embodiments, the source/drain region 112 is formed by: selectively forming the first layer of source/drain material 112A on the sloped sidewalls 54S of the second semiconductor material 54 and on the upper surface 90U of the fin 90 exposed by the opening 110, then forming the second layer of source/drain material 112B on the first layer of the source/drain material 112A to fill the opening 110. In some embodiments, the first layer of source/drain material 112A was formed selectively on the sloped sidewalls 54S and on the upper surface 90U, because the epitaxial source/drain material does not grow on the surface of the inner spacers 55. Once the first layer of source/drain material 112A is formed, the second layer of source/drain material 112B is grown on the first layer of source/drain material 112A to fill the opening 110.

The epitaxial process to grow the source/drain regions 112 and/or the implantation process to implant the second dopant in the source/drain regions 112 may be adjusted to achieve different concentrations of the second dopant in the first layer of source/drain material 112A and the second layer of source/drain material 112B. In some embodiments, the concentration of the second dopant (e.g., n-type impurities or p-type impurities) in the first layer of source/drain material 112A is lower than that in the second layer of source/drain material 112B. For example, the concentration of the second dopant in the first layer of source/drain material 112A may be between about 1E19/cm³ and about 3E21/cm³, and the concentration of the second dopant in the second layer of source/drain material 112B may be between about 1E20/cm³ and about 5E21/cm³.

In some embodiments, the concentration of the first dopant in the doped region 56 of an uppermost layer (e.g., furthest from the substrate 50) of the second semiconductor material 54 is equal to or higher than the concentration of the second dopant in the first layer of source/drain material 112A. Since the concentration of the first dopant in the doped regions 56 increases along the vertical direction toward the substrate 50, this means that the concentration of the first dopant in other, lower doped regions 56 (e.g., disposed closer to the substrate 50 than the uppermost doped region 56 furthest from the substrate 50) is higher than the concentration of the second dopant in the first layer of source/drain material 112A, in some embodiments.

In the illustrated embodiment, the second dopant in the source/drain regions 112 diffuses into the doped regions 56 of the second semiconductor material 54, which pushes the junction 57 in FIG. 7B further toward the middle portion of the second semiconductor material 54. In other words, the diffused second dopant increases the widths of the doped regions in the second semiconductor material 54. The doped regions with implanted first dopant, diffused first dopant, and diffused second dopant are labeled as doped regions 58 in FIG. 8D, and the boundaries 59 (e.g., interface) between the doped regions 58 and the undoped portions of the second semiconductor material 54 are shown in dashed lines in FIG. 8D. The boundaries 59 may also be referred to as junctions 59.

As illustrated in FIG. 8D, due to the contribution from the diffused second dopant, each of the doped regions 58 has a width D2 (e.g., a maximum width measured between the sloped sidewall 54S of the second semiconductor material 54 and the respective boundary 59 of the doped region 58) that is larger than the width D1 of the corresponding doped region 56 (e.g., at a same vertical distance from the substrate 50) in FIG. 7B. In addition, due to the diffused second dopant, each doped region 58 includes the first dopant and the second dopant, and a total concentration of the first dopant and the second dopant in the doped region 58 may be higher than a concentration of the first dopant in a corresponding doped region 56. Similar to FIG. 7B, the total concentration of the first dopant and the second dopant in the doped regions 58 in FIG. 8D shows a gradient. In particular, the total concentration of the first dopant and the second dopant in the doped regions 58 increases along the vertical direction toward the substrate 50.

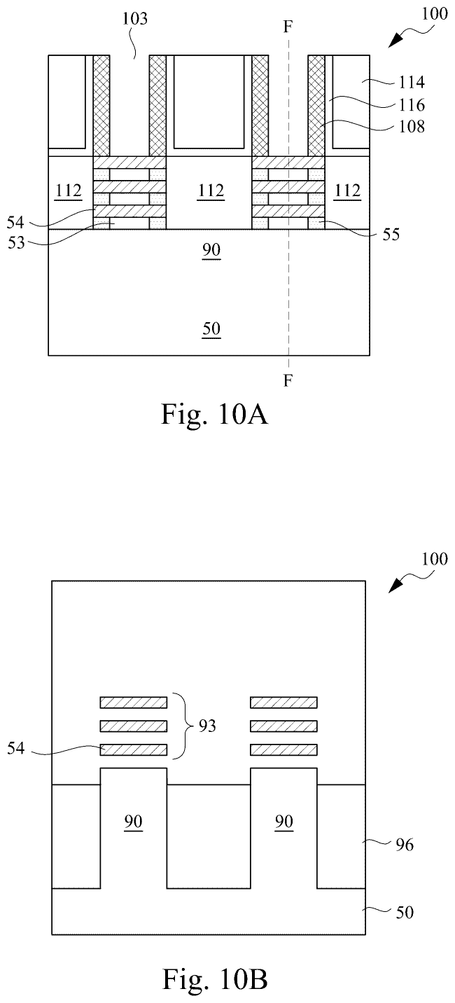

The doped regions 58 have higher carrier mobility and lower electrical resistance than an undoped regions (e.g., silicon) of the second semiconductor material 54, thus it may be advantageous to have large doped regions 58 in order to reduce the electrical resistance of the channel regions (see, e.g., 54 in FIGS. 10A, 11A, and 12A) of the NSFET device formed. The disclosed method herein achieves large doped regions 58 and avoids some performance issues with existing methods.

To appreciate the advantage of the presently disclosed method, consider a reference method where the ion implantation process 130 is omitted. In particular, after the openings 110 are formed, the reference method performs an etching process to recess the end portions of the second semiconductor material 54 exposed by the openings 110, thus forming sidewall recesses in the sidewalls of the second semiconductor material 54 facing the openings 110. Next, the source/drain regions 112 are formed in the openings 110. Portions of the source/drain regions 112 may protrude into the sidewall recesses of the second semiconductor material 54. The protruding portion of the source/drain regions 112 in the sidewall recesses, as well as portions of the second semiconductor material 54 with diffused second dopant from the source/drain regions 112, together may be considered as the doped regions of the reference method. However, the reference method has some performance issues. For example, due to process limitations, the depth of the sidewall recesses may be limited. In addition, without the ion implantation process 130, the concentration of dopant in the doped regions of the reference method may be limited. Furthermore, the etching process to recess the end portions of the second semiconductor material 54 may roughen the surfaces of the inner spacers 55 and the sidewalls of the second semiconductor material 54 exposed to the openings 110. The rough surfaces may be detrimental to the epitaxial process for growing the source/drain regions 112 and may degrade the quality of the epitaxial source/drain regions 112, thus limiting device performance. The present disclosure, by using the ion implantation process 130 and by controlling the process condition for the ion implantation process 130, achieves high dopant concentration and large size (e.g., width and/or volume) for the doped regions 56/58, while avoiding the etching process and the performance issues related with the rough surfaces of the inner spacers 55 and the sidewalls of the second semiconductor material 54 caused by the etching process. Note that the doped regions 56 of the present disclosure may be considered as replacing the protruding portions of the source/drain regions 112 in the reference method, therefore, the concentration of the first dopant in the doped region 56 should be comparable to (e.g., equal to, or higher than) the concentration of the second dopant in the first layer of source/drain material 112A.

Still referring to FIGS. 8A-8C, a contact etch stop layer (CESL) 116 is formed (e.g., conformally) over the source/drain regions 112 and over the dummy gate 102, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, plasma-enhanced CVD (PECVD), or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used. FIGS. 8B and 8C illustrate cross-sectional views of the NSFET device 100 of FIG. 8A, but along cross-section E-E and F-F in FIG. 8A, respectively.

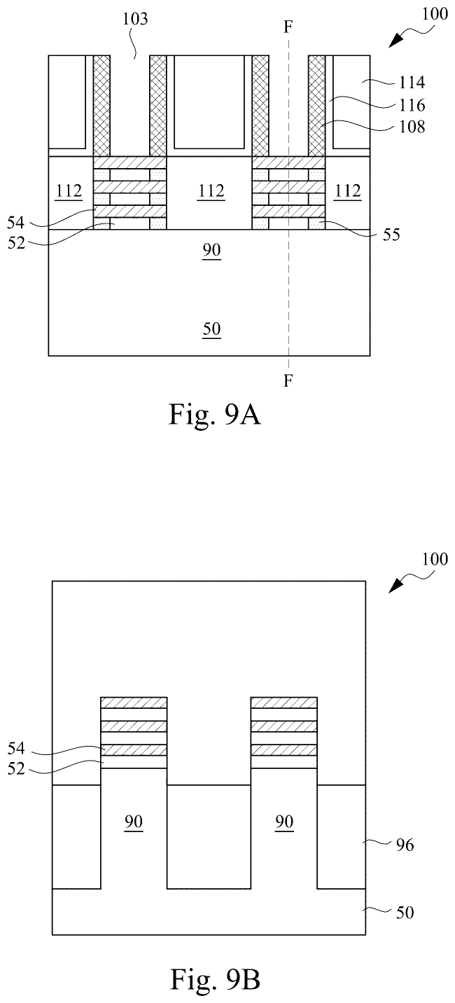

Next, in FIGS. 9A and 9B, the dummy gates 102 and the dummy gate dielectric 97 are removed. FIG. 9B illustrates the cross-sectional view of the NSFET device 100 of FIG. 9A along the cross-section F-F.

To remove the dummy gates 102, a planarization process, such as a CMP, is performed to level the top surfaces of the first ILD 114 and CESL 116 with the top surfaces of the dummy gates 102 and gate spacers 108. The planarization process may also remove the masks 104 (see FIG. 8A) on the dummy gates 102, and portions of the gate spacers 108 along sidewalls of the masks 104. After the planarization process, top surfaces of the dummy gates 102, gate spacers 108, CESL 116, and first ILD 114 are level. Accordingly, the top surfaces of the dummy gates 102 are exposed through the first ILD 114.

Next, the dummy gates 102 are removed in an etching step(s), so that recesses 103 are formed. In some embodiments, the dummy gates 102 are removed by an anisotropic dry etch process. For example, the etching process may include a dry etch process using reaction gas(es) that selectively etch the dummy gates 102 without etching the first ILD 114 or the gate spacers 108. During the removal of the dummy gates 102, the dummy gate dielectric 97 may be used as an etch stop layer when the dummy gates 102 are etched. The dummy gate dielectric 97 may then be removed after the removal of the dummy gates 102. An etching process, such as an isotropic etching process, may be performed to remove the dummy gate dielectric 97. In an embodiment, an isotropic etching process using an etching gas that comprises HF and NH₃ is performed to remove the dummy gate dielectric 97. As illustrated in FIGS. 9A and 9B, the recesses 103 expose the channel regions of the NSFET device. The channel regions are disposed between neighboring pairs of the epitaxial source/drain regions 112.

Next, in FIGS. 10A and 10B, the first semiconductor material 52 (e.g., portions exposed by the recesses 103) is removed to release the second semiconductor material 54. After the first semiconductor material 52 is removed, the second semiconductor material 54 (e.g., portions underlying the dummy gates 102 before the dummy gates 102 are removed) forms a plurality of nanostructures 54 that extend horizontally (e.g., parallel to the major upper surface of the substrate 50). The nanostructures 54 may be collectively referred to as the channel regions 93 or the channel layers 93 of the NSFET device 100 formed. As illustrated in FIG. 10A, gaps 53 (e.g., empty spaces) are formed between the nanostructures 54 by the removal of the first semiconductor material 52. In some embodiments, the nanostructures 54 are nanosheets or nanowires, depending on, e.g., the dimensions (e.g., size and/or aspect ratio) of the nanostructures 54.

In some embodiments, the first semiconductor material 52 is removed by a selective etching process using an etchant that is selective to (e.g., having a higher etch rate for) the first semiconductor material 52, such that the first semiconductor material 52 is removed without substantially attacking the second semiconductor material 54. In some embodiments, an isotropic etching process is performed to remove the first semiconductor material 52. The isotropic etching process is performed using an etching gas, and optionally, a carrier gas. The etching gas comprises F₂ and HF, and the carrier gas may be an inert gas such as Ar, He, N₂, combinations thereof, or the like, in some embodiments.

FIG. 10A illustrates the cross-sectional view of the NSFET device 100 along a longitudinal axis of the fin (e.g., along a current flow direction in the fin), and FIG. 10B illustrates the cross-sectional view of the NSFET device 100 along cross-section F-F, which is a cross-section along a direction perpendicular to the longitudinal axis of the fin and across middle portions of the nanostructures 54.

As illustrated in FIG. 10A, each of the nanostructures 54 has a rectangular shaped cross-section along the longitudinal axis of the fin. Similarly, in FIG. 10B, in a cross-section along a direction perpendicular to the longitudinal axis of the fin and across a middle portion of the nanostructure 54, each of the nanostructures 54 has a rectangular shaped cross-section.

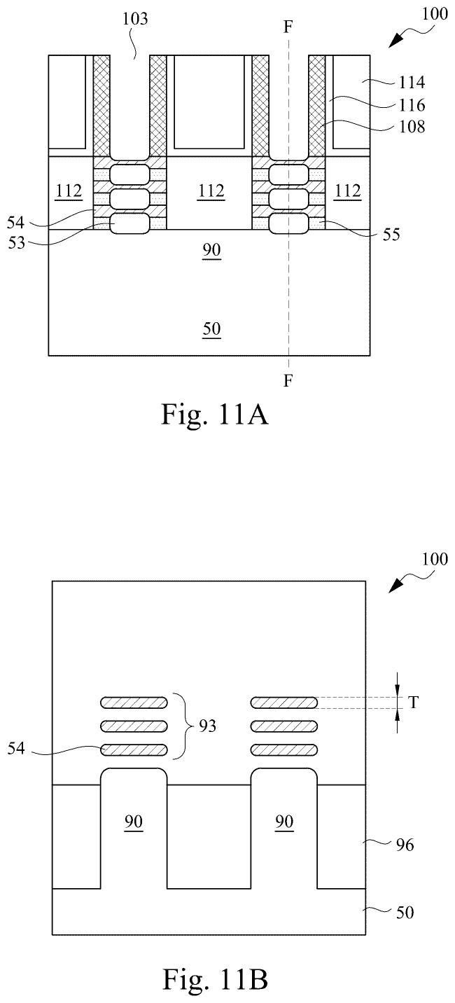

Next, in FIGS. 11A and 11B, the nanostructures 54 are reshaped by a nanostructure reshaping process (e.g., an isotropic etching process). In some embodiments, the nanostructures 54 are reshaped by a selective etching process using an etchant that is selective to the material of the nanostructures 54 (e.g., the second semiconductor material 54), such that the nanostructures 54 are etched without substantially attacking other materials in the NSFET device 100, such as oxide, silicon nitride, and low-K dielectric materials.

The nanostructure reshaping process thins the middle portion of each nanostructure 54 while the end portions of the nanostructure 54 (which are covered by the inner spacers 55 and the gate spacers 108) remain substantially unchanged, thus generating a dumbbell shaped cross-section for the nanostructure 54 in FIG. 11A. In addition, the nanostructure re-shaping process removes the sharp edges (e.g., see the 90-degree edges of the nanostructures 54 in FIG. 10B) of the nanostructures 54, thus generating rounded edges for each nanostructure 54 (see the rounded corners of each nanostructure 54 in FIG. 11B), as described in more details below.

As illustrated in FIG. 11A, after the nanostructure reshaping process, in the cross-section along the longitudinal axis of the fin, each of the nanostructures 54 has a dumbbell shape, where end portions of the nanostructure 54 (e.g., portions physically contacting the source/drain regions 112) have a thickness (measured along the vertical direction of FIG. 11A) larger than that of the middle portion (e.g., a portion mid-way between the end portions). In the example of FIG. 11A, the upper surface and the lower surface of the middle portion of each nanostructure 54 are illustrated as level surfaces (e.g., flat surfaces). This is, of course, merely a non-limiting example. In some embodiments, the upper surface and lower surface of the middle portion of each nanostructure 54 are curved, such as curved toward a horizontal center axis of the nanostructure 54. In addition, in the cross-section of FIG. 11B, each of the nanostructures 54 has a stadium shape (may also be referred to as a racetrack shape, a discorectangle shape, an obround shape, or a sausage body shape). In particular, in the cross-section of FIG. 11B, the corners of each nanostructure 54 are rounded (e.g., curved). In some embodiments, a thickness T (also referred to as sheet thickness) of the nanostructure 54 (e.g., nanosheet) is between about 1 nm and about 20 nm, and a length L1 (see FIG. 6D) of the nanostructure 54 is between about 1 nm and about 50 nm. The number of nanostructures 54 in an NSFET may be between 1 and 10, as an example, although any other suitable numbers may also be used.

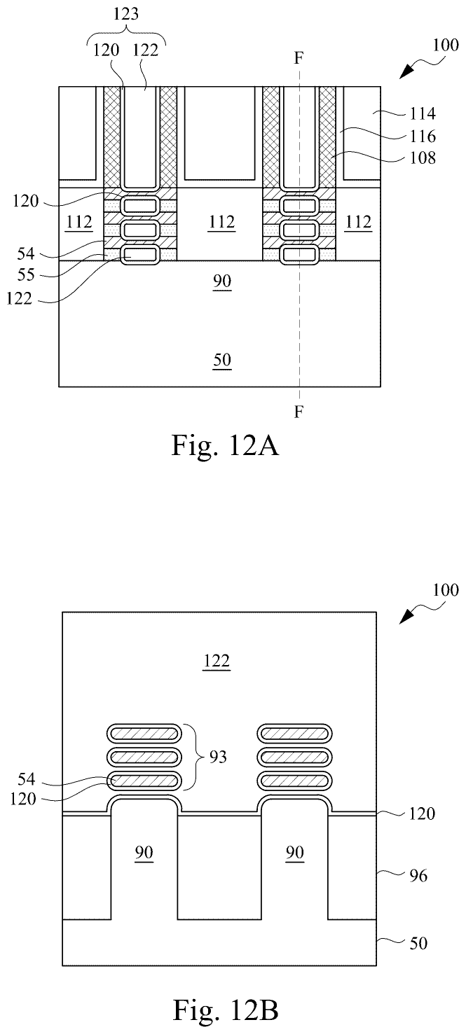

As feature sizes continue to shrink in advanced processing nodes, the distance between adjacent nanostructures 54 may become so small that it may be difficult to form layers (e.g., gate dielectric layer, work function layers) around the nanostructures 54 in subsequent processing. By reshaping the nanostructures 54, e.g., thinning the middle portions of the nanostructures 54, the distance between adjacent nanostructures 54 is increased, thus making it easier to form, e.g., gate dielectric layer 120 (see FIGS. 12A and 12B) around the nanostructures 54. In addition, since the thickness T of the nanostructures 54, which form the channel regions 93 of the NSFET device 100, is reduced by the nanostructure reshaping process, it is easier to control (e.g., turning on or off) the NSFET device 100 by applying a gate control voltage on the metal gate formed in subsequent processing.

In some embodiments, the nanostructure reshaping process illustrated in FIGS. 11A and 11B is omitted. In subsequent figures, the channel regions 93 of the NSFET device 100 are illustrated as having the cross-sections of FIGS. 11A and 11B, with the understanding that the channel regions 93 may have the cross-sections of FIGS. 10A and 10B (e.g., when the nanostructure reshaping process is omitted).

Next, in FIGS. 12A and 12B, a gate dielectric material 120 and a gate electrode material 122 are formed to form replacement gates. The gate dielectric material 120 is deposited conformally in the recesses 103, such as on the top surfaces and the sidewalls of the semiconductor fins 90, and on sidewalls of the gate spacers 108. The gate dielectric material 120 may also be formed on the top surface of the first ILD 114. Notably, the gate dielectric material 120 is formed to wrap around the nanostructures 54. In accordance with some embodiments, the gate dielectric material 120 comprises silicon oxide, silicon nitride, or multilayers thereof. In some embodiments, the gate dielectric material 120 is formed of a high-k dielectric material, and in these embodiments, the gate dielectric material 120 may have a k value greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, the gate electrode material 122 is deposited over and around the gate dielectric material 120, and fill the remaining portions of the recesses 103. The gate electrode material 122 may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill material (e.g., a fill metal, an electrically conductive material). After the filling of the gate electrode material 122, a planarization process, such as a CMP, may be performed to remove the excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120 of the replacement gates of the resulting NSFET device 100, respectively. Each gate electrode 122 and the corresponding gate dielectric layer 120 may be collectively referred to as a gate stack 123, a replacement gate structure 123, a metal gate structure 123, or a gate structure 123. Each gate structure 123 extends around the respective nanostructures 54.

Additional processing may be performed to finish fabrication of the NSFET device 100, as one of ordinary skill readily appreciates, thus details may not be discussed here. For example, a second ILD may be formed over the first ILD 114, and source/drain contacts may be formed to extend through the second ILD and the first ILD 114 to electrically coupled to the source/drain regions 112. Gate contacts may be formed to extend through the second ILD to electrically coupled to the gate structures 123. In addition, interconnect structures that include conductive lines and vias may be formed in the backend-of-the-line (BEOL) processing to interconnect the electrical components formed in/on the substrate 50 to form functional circuits.

Embodiments may achieve advantages. The disclosed method and structure provide large doped regions 56/58 with high dopant concentration in the nanostructures 54, which reduces the electrical resistance of the channel regions of the NSFET device formed and improve the electrical performance of the NSFET device. Compared with a reference method which omits the ion implantation process 130 and uses an etching process to recess the second semiconductor material 54, the disclosed method avoids performance issues related with rough sources caused by the etching process. In addition, the sloped sidewalls 54S of the second semiconductor material 54 facilitate the implantation of the first dopant into the second semiconductor material 54, and achieves higher dopant concentration in the doped regions.

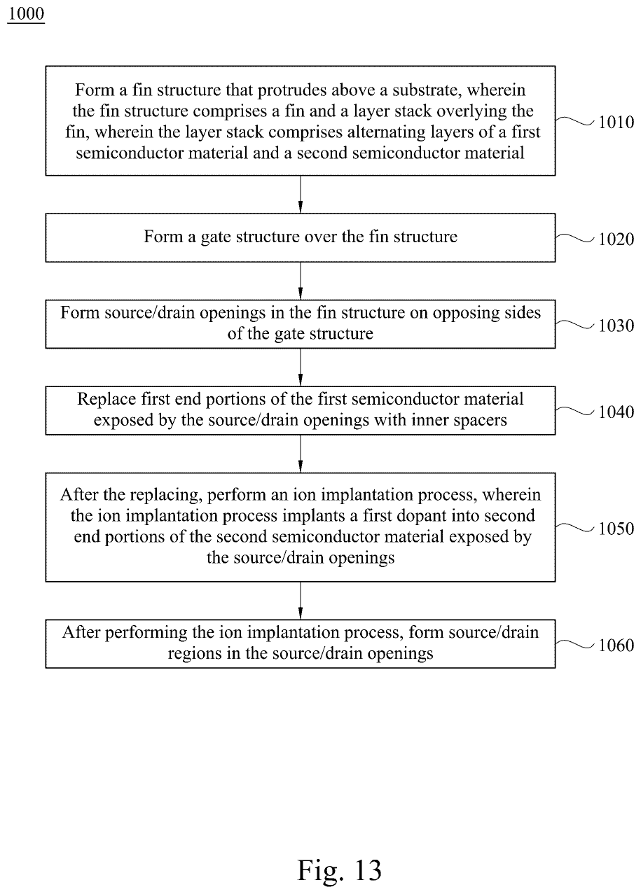

FIG. 13 illustrates a flow chart of a method 1000 of forming a semiconductor device, in accordance with some embodiments. It should be understood that the embodiment method shown in FIG. 13 is merely an example of many possible embodiment methods. One of ordinary skill in the art would recognize many variations, alternatives, and modifications. For example, various steps as illustrated in FIG. 13 may be added, removed, replaced, rearranged, or repeated.

Referring to FIG. 13, at block 1010, a fin structure that protrudes above a substrate is formed, wherein the fin structure comprises a fin and a layer stack overlying the fin, wherein the layer stack comprises alternating layers of a first semiconductor material and a second semiconductor material. At block 1020, a gate structure is formed over the fin structure. At block 1030, source/drain openings are formed in the fin structure on opposing sides of the gate structure. At block 1040, first end portions of the first semiconductor material exposed by the source/drain openings are replaced with inner spacers. At block 1050, after the replacing, an ion implantation process is performed, wherein the ion implantation process implants a first dopant into second end portions of the second semiconductor material exposed by the source/drain openings. At block 1060, after performing the ion implantation process, source/drain regions are formed in the source/drain openings.

In an embodiment, a method of forming a semiconductor device includes: forming a fin structure that protrudes above a substrate, wherein the fin structure comprises a fin and a layer stack overlying the fin, wherein the layer stack comprises alternating layers of a first semiconductor material and a second semiconductor material; forming a gate structure over the fin structure; forming source/drain openings in the fin structure on opposing sides of the gate structure; replacing first end portions of the first semiconductor material exposed by the source/drain openings with inner spacers; after the replacing, performing an ion implantation process, wherein the ion implantation process implants a first dopant into second end portions of the second semiconductor material exposed by the source/drain openings; and after performing the ion implantation process, forming source/drain regions in the source/drain openings. In an embodiment, the method further comprises, after forming the source/drain regions: forming a dielectric layer over the source/drain regions around the gate structure; and replacing the gate structure with a replacement gate structure. In an embodiment, replacing the gate structure comprises: removing the gate structure to form a recess in the dielectric layer, wherein the recess exposes first portions of the first semiconductor material and second portions of the second semiconductor material; after removing the gate structure, selectively removing the first portions of the first semiconductor material, wherein after the selectively removing, the second portions of the second semiconductor material remain to form a plurality of nanostructures; forming a gate dielectric material around the plurality of nanostructures; and forming a gate electrode material around the gate dielectric material. In an embodiment, the source/drain openings are formed to have sloped sidewalls such that a width of the source/drain openings decreases as the source/drain openings extend toward the substrate. In an embodiment, the first dopant is implanted into the second end portions of the second semiconductor material to form doped regions in the second semiconductor material, wherein a concentration of the first dopant in the doped regions increases along a depth direction of the source/drain openings toward the substrate. In an embodiment, a first doped region in an uppermost layer of the second semiconductor material distal from the substrate has a first concentration of the first dopant, and a second doped region in a lowermost layer of the second semiconductor material closest to the substrate has a second concentration of the first dopant, wherein the second concentration is between about twice and about five times of the first concentration. In an embodiment, the method further comprises, after performing the ion implantation process, performing a thermal process to activate the first dopant. In an embodiment, forming the source/drain regions comprises: selectively forming a first layer of source/drain material on the second end portions of the second semiconductor material and on an upper surface of the fin exposed by the source/drain openings; and after selectively forming the first layer of source/drain material, forming a second layer of source/drain material to fill the source/drain openings, wherein the source/drain regions are formed to have a second dopant, wherein a first concentration of the second dopant in the first layer of source/drain material is lower than a second concentration of the second dopant in the second layer of source/drain material. In an embodiment, a first doped region in an uppermost layer of the second semiconductor material distal from the substrate has a first concentration of the first dopant, wherein the first concentration of the first dopant is equal to or higher than the first concentration of the second dopant in the first layer of source/drain material. In an embodiment, the second dopant and the first dopant are of a same n-type or p-type. In an embodiment, the second dopant in the source/drain regions diffuses into the doped regions of the second semiconductor material, wherein the diffused second dopant increases volumes of the doped regions.

In an embodiment, a method of forming a semiconductor device includes: forming a fin structure that protrudes above a substrate, wherein the fin structure comprises a fin and alternating layers of a first semiconductor material and a second semiconductor material over the fin; forming a dummy gate structure over the fin structure; forming source/drain openings in the fin structure on opposing sides of the dummy gate structure; forming inner spacers between adjacent layers of the second semiconductor material; after forming the inner spacers, implanting a first dopant into end portions of the second semiconductor material exposed by the source/drain openings; after implanting the first dopant, forming source/drain regions in the source/drain openings, wherein the source/drain regions are formed to have a second dopant; forming a dielectric layer around the dummy gate structure; and replacing the dummy gate structure with a replacement gate structure. In an embodiment, replacing the dummy gate structure comprises: removing the dummy gate structure to form a recess in the dielectric layer, wherein the recess exposes first portions of the first semiconductor material and second portions of the second semiconductor material; after removing the dummy gate structure, selectively removing the first portions of the first semiconductor material, wherein after the selectively removing, the second portions of the second semiconductor material remain to form nanostructures; forming a gate dielectric material around the nanostructures; and forming a gate electrode material around the gate dielectric material. In an embodiment, the nanostructures are formed to have opposing sloped sidewalls facing the source/drain regions, wherein a length of the nanostructures, measured between the opposing sloped sidewalls of the nanostructures, increases along a depth direction of the source/drain openings toward the substrate. In an embodiment, the first dopant and the second dopant are of a same n-type or p-type, wherein the second dopant diffuses into the nanostructures, wherein the first dopant and the second dopant in the nanostructures are disposed in doped regions of the nanostructures. In an embodiment, a total concentration of the first dopant and the second dopant in the doped regions of the nanostructures increases along a depth direction of the source/drain openings toward the substrate.

In an embodiment, a semiconductor device includes: a substrate; a fin protruding above the substrate; a gate structure over the fin; source/drain regions over the fin on opposing sides of the gate structure; and nanostructures between the source/drain regions and under the gate structure, wherein the nanostructures are channel regions of the semiconductor device and comprise doped regions in contact with the source/drain regions and undoped regions between the doped regions, wherein the doped regions comprise a channel material and a first dopant in the channel material, wherein a dopant concentration in the doped regions increases along a first direction perpendicular to a major upper of the substrate, wherein the first direction extends from an uppermost nanostructure distal from the substrate toward a lowermost nanostructure closest to the substrate. In an embodiment, a first doped region in a first nanostructure of the nanostructures has a first width, and a second doped region in a second nanostructure of the nanostructures has a second width larger than the first width, wherein the second nanostructure is closer to the substrate than the first nanostructure, wherein the first width and the second width are measured along a current flow direction in the channel regions. In an embodiment, the nanostructures have opposing sloped sidewalls facing the source/drain regions, wherein a width of the nanostructures, measured between the opposing sloped sidewalls of the nanostructures, increases along the first direction. In an embodiment, the source/drain regions comprise a second dopant, wherein the doped regions of the nanostructures further comprise the second dopant, wherein the dopant concentration in the doped regions is a total concentration of the first dopant and the second dopant in the doped regions.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a fin structure that protrudes above a substrate, wherein the fin structure comprises a fin and a layer stack overlying the fin, wherein the layer stack comprises alternating layers of a first semiconductor material and a second semiconductor material;
forming a gate structure over the fin structure;
forming source/drain openings in the fin structure on opposing sides of the gate structure;
replacing first end portions of the first semiconductor material exposed by the source/drain openings with inner spacers;
after the replacing, performing an ion implantation process, wherein the ion implantation process implants a first dopant into second end portions of the second semiconductor material exposed by the source/drain openings; and
after performing the ion implantation process, forming source/drain regions in the source/drain openings.

2. The method of claim 1, further comprising, after forming the source/drain regions:
forming a dielectric layer over the source/drain regions around the gate structure; and
replacing the gate structure with a replacement gate structure.

3. The method of claim 2, wherein replacing the gate structure comprises:
removing the gate structure to form a recess in the dielectric layer, wherein the recess exposes first portions of the first semiconductor material and second portions of the second semiconductor material;
after removing the gate structure, selectively removing the first portions of the first semiconductor material, wherein after the selectively removing, the second portions of the second semiconductor material remain to form a plurality of nanostructures;
forming a gate dielectric material around the plurality of nanostructures; and
forming a gate electrode material around the gate dielectric material.

4. The method of claim 1, wherein the source/drain openings are formed to have sloped sidewalls such that a width of the source/drain openings decreases as the source/drain openings extend toward the substrate.

5. The method of claim 4, wherein the first dopant is implanted into the second end portions of the second semiconductor material to form doped regions in the second semiconductor material, wherein a concentration of the first dopant in the doped regions increases along a depth direction of the source/drain openings toward the substrate.

6. The method of claim 5, wherein a first doped region in an uppermost layer of the second semiconductor material distal from the substrate has a first concentration of the first dopant, and a second doped region in a lowermost layer of the second semiconductor material closest to the substrate has a second concentration of the first dopant, wherein the second concentration is between about twice and about five times of the first concentration.

7. The method of claim 5, further comprising, after performing the ion implantation process, performing a thermal process to activate the first dopant.

8. The method of claim 5, wherein forming the source/drain regions comprises:
selectively forming a first layer of source/drain material on the second end portions of the second semiconductor material and on an upper surface of the fin exposed by the source/drain openings; and
after selectively forming the first layer of source/drain material, forming a second layer of source/drain material to fill the source/drain openings, wherein the source/drain regions are formed to have a second dopant, wherein a first concentration of the second dopant in the first layer of source/drain material is lower than a second concentration of the second dopant in the second layer of source/drain material.

9. The method of claim 8, wherein a first doped region in an uppermost layer of the second semiconductor material distal from the substrate has a first concentration of the first dopant, wherein the first concentration of the first dopant is equal to or higher than the first concentration of the second dopant in the first layer of source/drain material.

10. The method of claim 9, wherein the second dopant and the first dopant are of a same n-type or p-type.

11. The method of claim 10, wherein the second dopant in the source/drain regions diffuses into the doped regions of the second semiconductor material, wherein the diffused second dopant increases volumes of the doped regions.

12. A method of forming a semiconductor device, the method comprising:
forming a fin structure that protrudes above a substrate, wherein the fin structure comprises a fin and alternating layers of a first semiconductor material and a second semiconductor material over the fin;
forming a dummy gate structure over the fin structure;
forming source/drain openings in the fin structure on opposing sides of the dummy gate structure;
forming inner spacers between adjacent layers of the second semiconductor material;
after forming the inner spacers, implanting a first dopant into end portions of the second semiconductor material exposed by the source/drain openings;
after implanting the first dopant, forming source/drain regions in the source/drain openings, wherein the source/drain regions are formed to have a second dopant;
forming a dielectric layer around the dummy gate structure; and
replacing the dummy gate structure with a replacement gate structure.

13. The method of claim 12, wherein replacing the dummy gate structure comprises:
removing the dummy gate structure to form a recess in the dielectric layer, wherein the recess exposes first portions of the first semiconductor material and second portions of the second semiconductor material;
after removing the dummy gate structure, selectively removing the first portions of the first semiconductor material, wherein after the selectively removing, the second portions of the second semiconductor material remain to form nanostructures;
forming a gate dielectric material around the nanostructures; and
forming a gate electrode material around the gate dielectric material.

14. The method of claim 13, wherein the nanostructures are formed to have opposing sloped sidewalls facing the source/drain regions, wherein a length of the nanostructures, measured between the opposing sloped sidewalls of the nanostructures, increases along a depth direction of the source/drain openings toward the substrate.

15. The method of claim 14, wherein the first dopant and the second dopant are of a same n-type or p-type, wherein the second dopant diffuses into the nanostructures, wherein the first dopant and the second dopant in the nanostructures are disposed in doped regions of the nanostructures.

16. The method of claim 15, wherein a total concentration of the first dopant and the second dopant in the doped regions of the nanostructures increases along a depth direction of the source/drain openings toward the substrate.

17. A semiconductor device comprising:
a substrate;
a fin protruding above the substrate;
a gate structure over the fin;
source/drain regions over the fin on opposing sides of the gate structure; and
nanostructures between the source/drain regions and under the gate structure, wherein the nanostructures are channel regions of the semiconductor device and comprise doped regions in contact with the source/drain regions and undoped regions between the doped regions, wherein the doped regions comprise a channel material and a first dopant in the channel material, wherein a dopant concentration in the doped regions increases along a first direction perpendicular to a major upper of the substrate, wherein the first direction extends from an uppermost nanostructure distal from the substrate toward a lowermost nanostructure closest to the substrate.

18. The semiconductor device of claim 17, wherein a first doped region in a first nanostructure of the nanostructures has a first width, and a second doped region in a second nanostructure of the nanostructures has a second width larger than the first width, wherein the second nanostructure is closer to the substrate than the first nanostructure, wherein the first width and the second width are measured along a current flow direction in the channel regions.

19. The semiconductor device of claim 17, wherein the nanostructures have opposing sloped sidewalls facing the source/drain regions, wherein a width of the nanostructures, measured between the opposing sloped sidewalls of the nanostructures, increases along the first direction.

20. The semiconductor device of claim 17, wherein the source/drain regions comprise a second dopant, wherein the doped regions of the nanostructures further comprise the second dopant, wherein the dopant concentration in the doped regions is a total concentration of the first dopant and the second dopant in the doped regions.
